(19) United States
(12) Patent Application Publication
(10) Pub. No.: US 2026/0036615 A1
(43) Pub. Date: Feb. 5, 2026

(54) TESTING STATION, TESTING MODULES AND TESTING METHOD FOR TESTING OPERATION OF A PLURALITY OF IMAGE INTENSIFIER TUBES

(71) Applicant: General Starlight Co. Inc., Woodbridge (CA)

(72) Inventor: Simon CHENDEROVITCH, Vaughan (CA)

(21) Appl. No.: 19/286,481

(22) Filed: Jul. 31, 2025

Related U.S. Application Data
(60) Provisional application No. 63/678,984, filed on Aug. 2, 2024.

(51) Int. Cl. G01R 31/25; G01R 1/04

(52) U.S. Cl. CPC G01R 31/257; G01R 1/0416

(57) ABSTRACT

The present disclosure provides a testing station, testing module and testing method for testing a plurality of image intensifier tubes. In an embodiment, a testing station includes a first testing module and a second testing module. The first testing module has a first input connector, a first output connector and a plurality of first testing sections each configured to test an image intensifier tube. The second testing module has a second input connector, a second output connector and a plurality of second testing sections each configured to test an image intensifier tube. The first testing module and the second testing module are configured to be removably attached to each other in a first orientation and a second orientation. The first input connector is connected to the second output connector in the first orientation, and the second input connector is connected to the first output connector in the second orientation.

### PRIORITY CLAIM

This application claims priority to U.S. Provisional Application No. 63/678,984, filed Aug. 2, 2024 and entitled “Test Station,” the entire contents of which is incorporated herein by reference and relied upon.

### TECHNICAL FIELD

The present disclosure generally relates to a testing station, a testing module and a testing method for simultaneously testing operation of a plurality of image intensifier tubes. More specifically, the present disclosure generally relates to a scalable test station that can be reconfigured with different numbers of testing modules to simultaneously test different numbers of image intensifier tubes.

### BACKGROUND

Image intensification, the basis of night vision, is a complex conversion of energy particles that occurs within a vacuum tube. An image-intensifier system works by collecting photons through an objective lens, converting them to electrons via a photocathode, increasing the electrical energy with a microchannel plate (MCP), converting the electrical energy back to light using a phosphor screen, and presenting the image for viewing through an eyepiece lens.

Image intensifier tubes are critical components in night vision systems. These tubes are widely used in military, law enforcement, aviation and medical imaging applications. For example, night vision monocular and binocular eyepieces typically include one or more image intensifier tubes. The performance of an image intensifier tube is influenced by several parameters including gain, resolution, signal-to-noise ratio, distortion and uniformity. Existing testing methods rely on bulky equipment that can require specialized training and time-consuming calibration. The existing methods can introduce variability in test conditions and make it difficult to perform fast, repeatable and field-portable assessments.

### SUMMARY

Due to their precision and complexity, image intensifier tubes must undergo thorough testing during manufacturing, integration and maintenance to ensure proper functionality and compliance with performance standards. The present disclosure provides a compact, reliable, scalable and user-friendly testing station for simultaneously testing a plurality of image intensifier tubes.

The disclosed testing station is a programmable modular system that applies voltage pulses with programmable voltage, length and pause to check and measure each image intensifier tube's response current and allows a user to simultaneously test multiple image intensifier tubes. The testing modules are “daisy-chained,” i.e., can be connected to and/or disconnected from one another to allow scaling. The testing modules can be easily installed and paired with a personal computer. The testing station further includes an advanced monitoring system with preprogrammed thresholds and timings, user configurable test parameters and data logging, making the daisy chained testing modules a useful yet compact tool to efficiently test and evaluate dozens to hundreds of image intensifier tubes simultaneously. The disclosed testing station is further configured for “burn-in” and “power cycling” test phases.

A first aspect of the present disclosure is to provide a testing station for testing a plurality of image intensifier tubes. The testing station includes a first testing module and a second testing module. The first testing module includes a first input connector and a first output connector, and a plurality of first testing sections each configured to receive and test a respective image intensifier tube. The second testing module includes a second input connector, a second output connector, and a plurality of second testing sections each configured to receive and test a respective image intensifier tube. The first testing module and the second testing module are configured to be removably attached to each other in a first orientation and a second orientation. The first input connector is connected to the second output connector in the first orientation, and the second input connector is connected to the first output connector in the second orientation.

A second aspect of the present disclosure is to provide a testing module configured to test a plurality of image intensifier tubes. The testing module includes a substrate, a plurality of testing sections, an input connector and an output connector. The substrate has a testing surface, a first side edge and a second side edge opposite the first side edge. The plurality of testing sections are located on the testing surface. The testing sections are each configured to receive and test an individual image intensifier tube. The input connector is located at the first side edge of the testing surface and is configured to removeably connect to an adjacent output connector of a first adjacent testing module. The output connector is located at the second side of the testing surface and is configured to removeably connect to an adjacent input connector of a second adjacent testing module.

A third aspect of the present disclosure is to provide a method of simultaneously testing a plurality of image intensifier tubes. The method includes configuring a testing board by connecting a plurality of testing modules together or disconnecting one or more of the testing modules from the remainer of the plurality of testing modules forming the testing board, connecting an input connector of one of the plurality of testing modules forming the testing board to a power supply unit, connecting an output connector of one of the plurality of testing modules forming the testing board to a computer, placing a plurality of image intensifier tubes on the plurality of testing modules forming the testing board, and simultaneously testing operation of the plurality of image intensifier tubes using the power source, the testing board and the computer.

Other objects, features, aspects and advantages of the systems and methods disclosed herein will become apparent to those skilled in the art from the following detailed description, which, taken in conjunction with the annexed drawings, discloses exemplary embodiments of the disclosed systems and methods.

### BRIEF DESCRIPTION OF THE DRAWINGS

Referring now to the attached drawings which form a part of this original disclosure:

FIGS. 1A and 1B illustrate perspective views of example embodiments of image intensifier tubes which can be tested by a testing station in accordance with the present disclosure;

FIG. 2 illustrates an example embodiment of a testing station connection diagram with a plurality of individual testing modules, a power supply unit and a computer;

FIG. 3 illustrates an example embodiment of an individual testing module in accordance with the present disclosure;

FIGS. 4 illustrates a perspective view of an example embodiment of a testing station including a testing board formed with a plurality of individual modules in accordance with the present disclosure; and

FIG. 5 illustrates an example embodiment of a method of simultaneously testing a plurality of image intensifier tubes in accordance with the present disclosure.

### DETAILED DESCRIPTION

Selected embodiments will now be explained with reference to the drawings. It will be apparent to those skilled in the art from this disclosure that the following descriptions of the embodiments are provided for illustration only and not for the purpose of limiting the invention as defined by the appended claims and their equivalents.

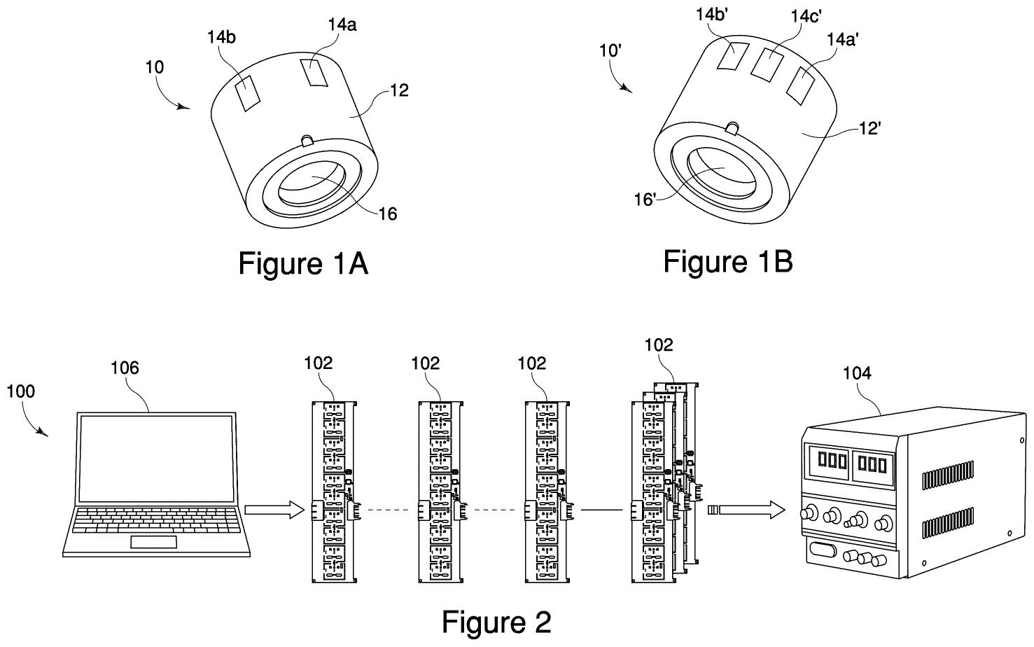

FIGS. 1A and 1B illustrate example embodiments of image intensifier tubes 10, 10′ that can be tested using a testing station 100 in accordance with the present disclosure. Each of the image intensifier tubes 10, 10′ includes a cylindrical housing 12, 12′, one or more electrical contacts 14, 14′ and one or more lens 16, 16′. More specifically, FIG. 1A illustrates one type of image intensifier tube 10 having a cylindrical housing 12, a first electrical contact 14a, a second electrical contact 14b, and one or more lens 16, while FIG. 1B illustrates another type of image intensifier tube 10′ having a cylindrical housing 12′, a first electrical contact 14a′, a second electrical contact 14b′, a third electrical contact 14c′ and one or more lens 16′. The third electrical contact 14c′ is present only on image intensifier tubes 10′ with manual gain control. The image intensifier tubes 10, 10′ also include other conventional components such as a phosphor layer, an anode, an electrostatic lens and a photocathode.

FIG. 2 illustrates a schematic diagram of an example embodiment of an image intensifier tube testing station 100 configured in accordance with the present disclosure. The testing station 100 is configured to simultaneously test operation of a plurality of image intensifier tubes 10, 10′ such as those shown in FIGS. 1A and 1B, as well as other image intensifier tubes 10, 10′ of similar construction.

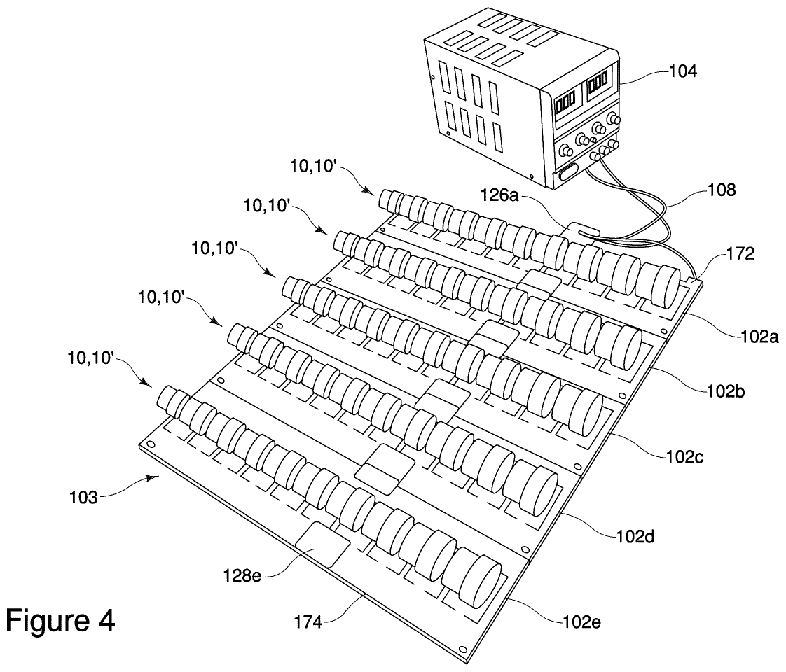

As seen in FIG. 2, the testing station 100 includes one or more individual testing modules 102, a power supply unit 104 and a computer 106. As seen in FIG. 4 and discussed in more detail below, a plurality of the individual testing modules 102 can be connected to each other in a linear or daisy chain manner to adjust the number of the plurality of image intensifier tubes 10, 10′ that can be tested simultaneously.

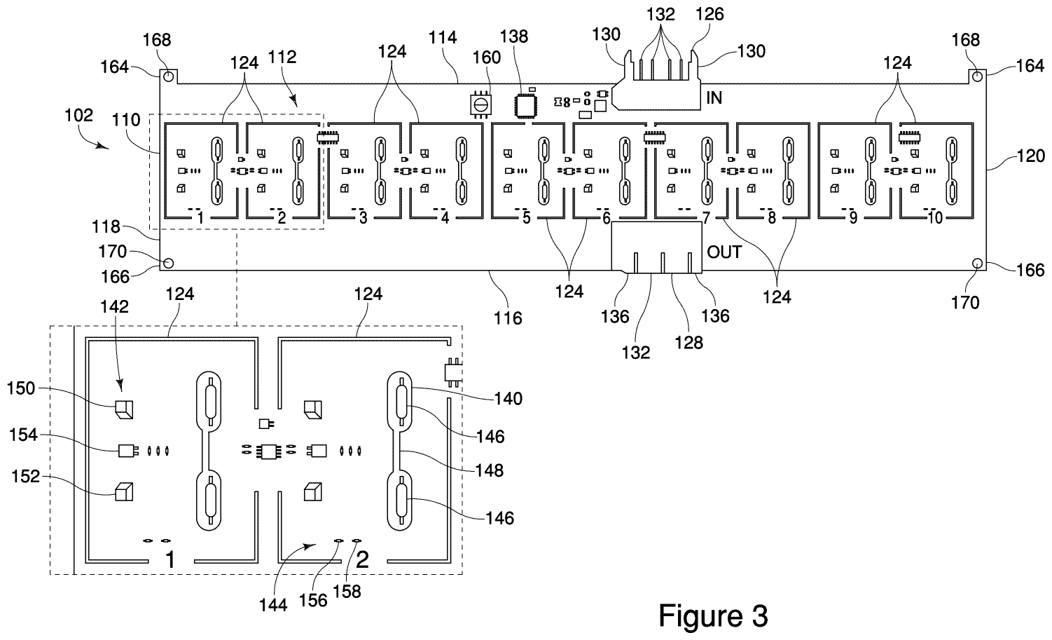

FIG. 3 illustrates an individual testing module 102 in more detail. The individual testing module 102 includes a substrate 110 having testing surface 112 and an opposite bottom surface, with the testing surface 112 shown in FIG. 3. The substrate 110 is a base circuit board. During testing, the bottom surface of the substrate 110 rests on a supporting surface such as a table or countertop, while the testing surface 112 of the substrate 110 faces upward so that the plurality of image intensifier tubes 10, 10′ can be set on top of the testing surface 112 during testing.

The testing surface 112 includes a first longitudinal side edge 114 and an opposite second longitudinal side edge 116 which extend in a longitudinal or length direction (horizontal in FIG. 3). The testing surface 112 also includes a first lateral side edge 118 and an opposite second lateral side edge 120 which extend in a lateral or width direction (vertical in FIG. 3). The testing surface 112 has a generally rectangular shape created by the first longitudinal side edge 114, the second longitudinal side edge 116, the first lateral side edge 118 and the second lateral side edge 120. The length of the testing surface 112 is longer than the width. That is, the length of the first longitudinal side edge 114 and the second longitudinal side edge 116 are longer than the length of the first lateral side edge 118 and the second lateral side edge 120. In the illustrated embodiment, the first longitudinal side edge 114 and the second longitudinal side edge 116 are each 410 mm long, and the first lateral side edge 118 and the second lateral side edge 120 are each 100 mm long. Thus, the ratio of the length to width is greater than 3:1, or more preferably greater than 4:1, to maximize the use of space when connecting the individual modules 102 to create a testing board 103 as shown in FIG. 4.

On the testing surface 112, each individual testing module 102 includes a plurality of testing sections 124 (or “nests”). Each testing section 124 is configured to test one image intensifier tube 10, 10′ at a time. The testing sections 124 are all aligned in the longitudinal or length direction of the first surface 112. That is, the testing sections 124 are only located in a single line in the longitudinal or length direction of the first surface 112. In the illustrated embodiment, the individual module 102 includes ten testing sections 124 which are aligned in a single line in the longitudinal or length direction and marked with numbers 1 to 10. This arrangement maximizes the use of space when connecting the individual modules 102 to create a testing board 103 as shown in FIG. 4.

As further seen in FIG. 3, the testing module 102 includes an input connector 126 and an output connector 128. Here, the input connector 126 is a male connector and the output connector 128 is a female connector, but the reverse configuration can also be used. The input connector 126 is configured to attach to an output connector 128 of another identical individual testing module 102. Similarly, the output connector 128 is configured to attach to an input connector 126 of another identical individual testing module 102. By configuring the testing modules 102 in this manner, a plurality of individual modules 102 can be stacked in a linear or daisy chain manner to form a testing board 103 as shown in FIG. 4. The input connector(s) 126 and the output connector(s) 128 each route power and communication interfaces during the image intensifier tube 10, 10′ testing process discussed below.

As seen in FIG. 4, the input connector 126 is configured to connect to both an output connector 128 of another identical individual testing module 102 and also to the power supply unit 104 via a wired connection 108. Similarly, the output connector 128 is configured to connect to both an input connector 128 of another identical individual testing module 102 and also to the computer 106 via a wired connection. In FIG. 4, five testing modules 102a, 102b, 102c, 102d, 102e are connected together in a linear or daisy chain manner to form a testing board 103. The output connector 128 of the first testing module 102a is connected to the input connector 126 of the adjacent second testing module 102b. The output connector 128 of the second testing module 102b is connected to the input connector 126 of the adjacent third testing module 102c. The output connector 128 of the third testing module 102c is connected to the input connector 126 of the adjacent fourth testing module 102d. The output connector 128 of the fourth testing module 102d is connected to the input connector 126 of the adjacent fifth testing module 102e. The input connector 126a of the first testing module 102a is connected to the power supply unit 104 via the wired connection 108. The output connector 128e of the fifth testing module 102e then connects to the computer 106 via another wired connection.

Referring again to FIG. 3, in the illustrated embodiment, the input connector 126 is located at the first longitudinal side edge 114 of the testing surface 112. More specifically, the input connector 126 is located adjacent to the first longitudinal side edge 114 and protrudes outward from the first longitudinal side edge 114 of the individual testing module 102 (upward in FIG. 3). Here, the input connector 126 protrudes outward from the first longitudinal side edge 114 in a direction generally perpendicular to the first longitudinal side edge 114. The input connector 126 also includes an attachment mechanism 130 and a plurality of pins 132 which protrude from the first longitudinal side edge 114 of the individual testing module 102. The attachment mechanism 130 and the plurality of pins 132 each protrudes outward from the first longitudinal side edge 114 in the direction generally perpendicular to the first longitudinal side edge 114.

In the illustrated embodiment, the output connector 128 is located at the second longitudinal side edge 116 of the testing surface 112. More specifically, the output connector 128 is located adjacent to the second longitudinal side edge 115 such that the outer edge 132 of the output connector 128 generally aligns with the second longitudinal side edge 115 from the top view shown in FIG. 3. The output connector 128 does not generally protrude outwardly from the second longitudinal side 115 in the lateral or width direction (downward in FIG. 3), which enables a plurality of individual testing modules 102 to be stacked in a linear or daisy chain manner with the respective first longitudinal side edge 114 aligned with and contacting the respective second longitudinal side edge 115 of the adjacent or neighboring testing module 102, as seen for example in FIG. 4.

The output connector 128 includes an attachment mechanism 134 and a plurality of pin receiving apertures which are aligned along the second longitudinal side 115. The attachment mechanism 134 receives and attaches to the attachment mechanism 130 of the input connector 126 of an adjacent testing module 102. The plurality of pin receiving apertures receive the plurality of pins 132 of the input connector 126 of the adjacent testing module 102.

Each module 102 includes a microcontroller (MCU) 138 configured to execute stored instructions and operate upon stored data. The MCU 138 controls the power and monitors the current on each of the image intensifier tubes 10, 10′ within each of the testing sections 124 of the module 102. The MCU 138 also controls communication between the other two module(s) 102 on opposite sides and/or the computer 106 connected to its own module 102 at the output connector 128. The MCU 138 can thus generally include a processor and memory as understood in the art. The processor is configured to execute instructions programmed into and/or stored by the memory. The memory can include, for example, a non-transitory storage medium.

As further seen in FIG. 3, each testing section 124 includes a support cradle 140, a contact portion 142 and a visible indicator 144. The support cradle 140 supports an individual image intensifier tube 10, 10′ above the substrate 110 during the testing process discussed below. The contact portion 142 contacts the electrical contacts 14, 14′ of an individual image intensifier tube 10, 10′ during the testing process. The visible indicator(s) 144 indicate whether the individual image intensifier tube 10, 10′ located within that testing section 124 has passed or failed the testing process and/or indicates current power.

In the illustrated embodiment, the support cradle 140 projects upward from the testing surface 112. More specifically, the support cradle 140 includes two side supports 146 and a bridge support 148 that project upward form the testing surface. The bridge support 148 is located between the side supports 146. The side supports 146 project upward further than the bridge support 148. The bridge support 148 has a concave curved surface that generally matches the curvature of the cylindrical housing 12, 12′ of the image intensifier tubes 10, 10′, enabling the cylindrical housing 12, 12′ to rest on the bridge support 148.

In the illustrated embodiment, the contact portion 142 includes one or more electrical contacts 150, 152, 154, namely, a first electrical contact 150, a second electrical contact 152 and a third electrical contact 154. The first electrical contact 150, the second electrical contact 152 and the third electrical contact 154 each project upwardly from the testing surface 112 to both support an image intensifier tube 10, 10′ and make contact with the electrical contacts 14, 14′ of the image intensifier tube 10, 10′. The first electrical contact 150 and the second electrical contact 152 are configured to measure power via electrical contact with respective electrical contacts 14, 14′ of the image intensifier tube 10, 10′. The third electrical contact 154 is configured to measure gain control via electrical contact with a respective electrical contact 14, 14′ of the image intensifier tube 10, 10′. When the image intensifier tube 10 of FIG. 1A is placed within a testing section 124, the first electrical contact 150 contacts the first electrical contact 14a and the second electrical contact 152 contacts the second electrical contact 14b. When the image intensifier tube 10′ of FIG. 1B is placed within a testing section 124, the first electrical contact 150 contacts the first electrical contact 14a′, the second electrical contact 152 contacts the second electrical contact 14b′, and the third electrical contact 154 contacts the third electrical contact 14c′.

In the illustrated embodiment, the visible indicator 144 includes a first visible indicator 156 and a second visible indicator 158. The visible indicators 144, 156, 158 can include LED lights and can signal current power state and/or a pass or fail state. Here, the first visible indicator 156 is a first light, and the second visible indicator 158 is a second light. The first light and the second light are different colors. For example, the first light is green, and the second light is red. When the first visible indicator 156 lights up during the testing process, the lighting indicates that the individual image intensifier tube 10, 10′ placed within that testing section 124 has passed all tests by meeting all predefined thresholds. When the second visible indicator 158 lights up during the testing process, the lighting indicates that the individual image intensifier tube 10, 10′ placed within that testing section 124 has failed one or more test by not meeting a predefined threshold.

In the illustrated embodiment, each individual testing module 102 includes a switch 160. Here, the switch 160 is a rotary switch 160 which enables a user to adjust the current threshold or other predefined parameters for testing the individual image intensifier tube 10, 10′ within each testing section 124. More specifically, the rotary switch 160 enables the user to choose from preset thresholds by actuating the rotary switch 160. Thus, when different modules 102 are connected together to form a testing board 103, the user can manually adjust the switch 103 of each module 102 to set different thresholds for different modules 102. In an embodiment, the user can assign any test parameter or threshold that can be selected or specified using a computer 106 to the rotary switch 160 for manual adjustment.

In the illustrate embodiment, each individual testing module 102 further includes one or more first substrate connector 164 and one or more second substrate connector 166. More specifically, the illustrated individual testing module 102 includes two first substrate connectors 164 located on opposite sides of the first longitudinal side edge 114 and two second substrate connectors 166 located on opposite sides of the second longitudinal side edge 116. The first substrate connectors 164 project outwardly from the first longitudinal side edge 114 (upward in FIG. 3) and each include an aperture 168 located outward from the first longitudinal side edge 114 where the first longitudinal side edge 114 meets each of the first lateral side edge 118 and the second lateral side edge 120. The second substrate connectors 166 each include a similarly sized aperture 170 located within the second longitudinal side edge 116 where the second longitudinal side edge 116 meets each of the first lateral side edge 118 and the second lateral side edge 120. When two testing module 102 are attached together, the apertures 168 overlap with the apertures 170 so that an attachment mechanism such as a pin or screw can be inserted therethrough to secure the testing module 102 to an adjacent testing module 102 so that they do not disengage during the testing process.

Two testing modules 102 can thus be attached together in multiple orientations. For example, a first testing module 102 can include a first input connector 126, a first output connector 128, and a plurality of first testing sections 124 each configured to receive and test a respective image intensifier tube 10, 10′, while a second testing module 102 can include a second input connector 126, a second output connector 128, and a plurality of second testing sections 124 each configured to receive and test a respective image intensifier tube 10, 10′. The first testing module 102 and the second testing module 102 are configured to be removably attached to each other in a first orientation and a second orientation. The first testing module 102 and the second testing module 102 will function the same in both the first orientation and the second orientation. The first input connector 126 is connected to the second output connector 128 in the first orientation, the second input connector 126 is connected to the first output connector 128 in the second orientation. The first longitudinal side edge 114 of the first module 102 is aligned with and contacts the second longitudinal side edge 116 of the second module 102 in the first orientation, and the first longitudinal side edge 114 of the second module 102 is aligned with and contacts the second longitudinal side edge 116 of the first module 102 in the second orientation. This configuration makes it easy to add and remove testing modules 102 as needed.

FIG. 4 shows a plurality of testing modules 102 attached in a daisy chain or linear manner by mating the input connectors 126 with the output connectors 128 of adjacent testing modules 102, and by mating the first substrate connectors 164 with the second substrate connectors 166 of the adjacent modules 102. In FIG. 4, five individual testing modules 102 are connected together to form a testing board 103 configured to test up to fifty image intensifier tubes 10, 10′ simultaneously, with each testing module 102 receiving up to ten image intensifier tubes 10, 10′. It is also possible to connect a different number of testing modules 102 together. For example, ten, twenty or thirty testing modules 102 can be connected together in the same manner.

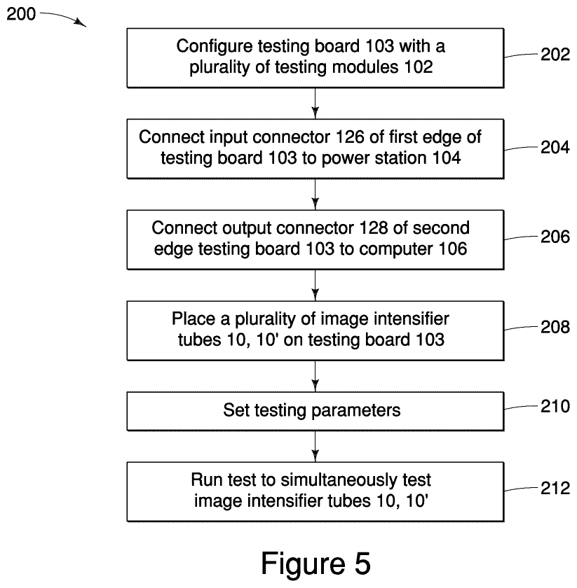

FIG. 5 illustrates an example embodiment of a method 200 of simultaneously testing a plurality of image intensifier tubes 10, 10′ in accordance with the present disclosure. Those of ordinary skill in the art will recognize from this disclosure that certain steps of the method 200 can be added, removed or altered without departing from the spirit and scope of the present disclosure.

At step 202, a user configures a testing board 103 with a plurality of testing modules 102. For example, the user can attach a plurality of individual testing modules 102 together to form a testing board 103, as seen for example in FIG. 4. To connect the individual testing modules 102 together, the user connects the respective input connectors 126 to the respective output connectors 128 of adjacent testing modules 102, with the first longitudinal side edge(s) 114 aligning with and contacting the second longitudinal side edge(s) 116 of adjacent testing modules 102. This leaves one unconnected input connector 126 at the first edge 172 of the testing board 103 (e.g., in FIG. 4, the unconnected input connector 126 of the testing module 102a, with the first longitudinal side edge 114 of the testing module 102a forming the first edge 172 of the testing board 103) and one unconnected output connector 128 at the second opposite edge 174 of the testing board 103 (e.g. in FIG. 4, the unconnected output connector 128 of the testing module 102e, with the second longitudinal side edge 116 of the testing module 102e forming the second edge 174 of the testing board 103). The user further secures the modules 102 together by aligning the first substrate connector(s) 164 and the second substrate connector(s) 166 of adjacent testing modules 102 and inserting a mechanical connector through the respective apertures 168, 170.

The user can also configure the testing board 103 by disconnecting one or more of the testing modules 102 from the remainer of the plurality of testing modules 102 forming the testing board 103. The user disconnects adjacent testing modules 102 by disconnecting the respective input connector 126 and output connector 128 and by disconnecting the respective first substrate connector 164 and the second substrate connector 166. A user may wish to remove a testing module 102, for example, to reduce the size of the testing board 103 or remove a faulty or damaged testing module 102.

At step 204, the user attaches the input connector 126 of the testing module 102 at the first edge 172 of the testing board 103 to the power supply unit 104. In FIG. 4, the user attaches the input connector 126 of the testing module 102a to the power supply unit 104. In an embodiment, the user attaches the input connector 126 to the power supply unit 104 via a wired connection 108.

At step 206, the user attaches the output connector 128 of the testing module 102 at the second edge 174 of the testing board 103 to the computer 106. In FIG. 4, the user attaches the output connector 128 of the testing module 102e to the computer 106. In an embodiment, the user attaches the output connector 128 to the computer 106 via a USB—UART cable.

At step 208, the user places a plurality of image intensifier tubes 10, 10′ on the testing modules 102 forming the testing board 103. The user places each image intensifier tube 10, 10′ within a testing section 124. The user places each image intensifier tube 10, 10′ so that the image intensifier tube 10, 10′ rests on the support cradle 140 with one or more electrical contacts 14, 14′ contacting one or more of the respective electrical contacts 150, 152, 154. The image intensifier tube 10, 10′ can also rest on one or more of the electrical contacts 150, 152, 154. The image intensifier tube 10, 10′ then rests within the testing section 124 with the respective visible indicator 144 for that testing section 124 exposed.

At step 210, the user sets the testing parameters. In different embodiments, the testing parameters can be set using the testing modules 102, the power supply unit 104, or the computer 106. The testing parameters can include one or more of a current threshold (e.g., no current, low current threshold, high current threshold), run time, on/off timing for how long to keep power cycling on/off, input voltage, input current, and supply voltage per image intensifier tube 10. In the illustrated embodiment, the user sets the current threshold using the switch 160 to select from a plurality of preset thresholds. The testing parameters can change, for example, for different types of image intensifier tubes 10, 10′ made by different manufacturers.

The user can adjust the thresholds using the module(s) 102 or the computer 106. Testing current consumption thresholds can be fine-adjusted by a computer 106 via a serial interface (e.g., RS232). In case of simplified setup without a computer 106, the rotary switch 160 can be used to select from preset thresholds. With a computer 106 connected to the test setup, the user can control every aspect of the testing parameters and thresholds: testing voltage, current thresholds, on-off period and duty cycle, manual gain control, and any other applicable parameters and thresholds. At step 212, the user runs a test which simultaneously tests operation of the image intensifier tubes 10, 10′. More specifically, the testing station 100 applies voltage pulses with a preprogrammed voltage, length and pause to check and measure the response current of each image intensifier tube 10, 10′. The test can be runs from the on time to the off time set by the user at step 210. During the test, the power supply unit 104 provides an input voltage and an input current to each of the plurality of image intensifier tubes 10, 10′ via the testing modules 102. The input voltage can be applied by the first electrical contact 150 or the second electrical contact 152. The input current can be applied by the third electrical contact 154. The input current can be, for example, up to 200 mA at 12 VDC input. The module 102 supply voltage can be, for example, between 5V to 15V. The testing section 124 supply voltage for the image intensifier tubes can be, for example, between 1.5V to 3V. That is, there is a step-down DC-DC converter in each testing module 102 that produces the 1.5V-3V (MCU 138 controlled) supply voltage for the image intensifier tubes 10, 10′ on the module 102. The MCU 138 further controls switches for each of the image intensifier tube 10, 10′ of each testing section 124 for on-off cycling. The test can include a current consumption test (i.e., current consumed per image intensifier tube 10) and/or a supply voltage test. During the test, the computer 106 tracks, displays and logs, for example, current consumption, power cycles, run time, manual gain control and/or other parameters.

During the test, the visible indicators 144 for each testing section 124 are activated based on whether the image intensifier tube 10, 10′ within that testing section 124 passes or fails one or more test. For example, the first visible indicator 156 illuminates green if the image intensifier tube 10, 10′ within that testing section 124 passed all tests, and the second visible indicator 158 illuminates red if the image intensifier tube 10, 10′ within that testing section 124 failed one or more test. This way, the user can quickly assess the functionality of the image intensifier tube 10, 10′ located within that testing section 124 with illuminated first visible indicators 156, and the user can remove those image intensifier tubes 10, 10′ and place them in a corresponding device such as a night vision device for further use. If the user wishes to review the details of why an image intensifier tube 10, 10′ failed a test, those details are available via the computer 106 interface.

The power supply unit 104 can be a programmable DC regulator power supply as known in the art. In an embodiment, the power supply unit 104 displays the current and voltage being applied to the testing modules 102. In an embodiment, the power supply unit 104 enables fine and course adjustments to current or voltage and low or high amps.

The computer 106 can be a standard laptop or desktop computer as known in the art which includes a processor configured to run testing software compatible with the modules 102. The testing software enables the user to set the testing parameters and/or number of modules 102 for the test and view the results of the test. The testing software also logs and displays results in various formats as needed. The computer 106 thus generally includes one or more processor and one or more memory. The processor is configured to execute instructions programmed into and/or stored by the memory. The memory can include, for example, a non- transitory storage medium.

In a further embodiment, each testing module 102 is equipped with calibrated light sources and light sensors for each of the testing sections 124 for an individual image intensifier tube 10, 10′, and manual gain control can be used to test the manual gain control response of each image intensifier tube 10, 10′.

The embodiments described herein provide improved testing stations, testing modules and testing methods for testing operation of a plurality of image intensifier tubes. The devices and methods are advantageous, for example, because they can test a plurality of image intensifier tubes in a compact, reliable, scalable and user-friendly manner. It should be understood that various changes and modifications to the systems and methods described herein will be apparent to those skilled in the art and can be made without diminishing the intended advantages.

### General Interpretations of Terms

In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Also, the terms “part,” “section,” “portion,” “member” or “element” when used in the singular can have the dual meaning of a single part or a plurality of parts. Also as used herein to describe the above embodiment, the following directional terms “forward”, “rearward”, “above”, “downward”, “vertical”, “horizontal”, “below” and “transverse” as well as any other similar directional terms refer to those directions.

The term “configured” as used herein to describe a component, section or part of a device includes hardware and/or software that is constructed to carry out the desired function.

While only selected embodiments have been chosen to illustrate the present invention, it will be apparent to those skilled in the art from this disclosure that various changes and modifications can be made herein without departing from the scope of the invention as defined in the appended claims. For example, the size, shape, location or orientation of the various components can be changed as needed and/or desired. Components that are shown directly connected or contacting each other can have intermediate structures disposed between them. The functions of one element can be performed by two, and vice versa. The structures and functions of one embodiment can be adopted in another embodiment. It is not necessary for all advantages to be present in a particular embodiment at the same time. Every feature which is unique from the prior art, alone or in combination with other features, also should be considered a separate description of further inventions by the applicant, including the structural and/or functional concepts embodied by such features. Thus, the foregoing descriptions of the embodiments according to the present invention are provided for illustration only, and not for the purpose of limiting the invention as defined by the appended claims and their equivalents.

What is claimed is:

1. A testing station for simultaneously testing a plurality of image intensifier tubes, the testing station comprising:
a first testing module including a first input connector, a first output connector, and a plurality of first testing sections each configured to receive and test a respective image intensifier tube;
a second testing module including a second input connector, a second output connector, and a plurality of second testing sections each configured to receive and test a respective image intensifier tube,
the first testing module and the second testing module configured to be removably attached to each other in a first orientation and a second orientation, the first input connector connected to the second output connector in the first orientation, the second input connector connected to the first output connector in the second orientation.

2. The testing station of claim 1, wherein
the first input connector and the second input connector are also configured to connect to a power unit such that the first input connector connects to the power unit in the second orientation and the second input connector connects to the power unit in the first orientation.

3. The testing station of claim 2, comprising the power unit, the power unit configured to apply an input voltage and an input current to each of the plurality of image intensifier tubes via the first and second testing modules.

4. The testing station of claim 1, wherein
the first output connector and the second output connector are also configured to connect to a computer such that the first output connector connects to the computer in the first orientation and the second output connector connects to the computer in the second orientation.

5. The testing station of claim 4, comprising the computer, the computer configured to display and log one or more of current consumption, power cycle, run time, or manual gain control for each of the plurality of image intensifier tubes.

6. The testing station of claim 1, wherein
the first testing module includes a first substrate with the plurality of first testing sections aligned in a single first row along the first substrate, and
the second testing module includes a second substrate with the plurality of second testing sections aligned in a single second row along the second substrate.

7. The testing station of claim 6, wherein
at least one of the first input connector and the first output connector extends from the first substrate in a direction generally perpendicular to the first row, and
at least one of the second input connector and the second output connector extends from the second substrate in a direction generally perpendicular to the second row.

8. A testing module configured to test a plurality of image intensifier tubes, the testing module comprising:
a substrate having a testing surface, a first side edge and a second side edge opposite the first side edge;
a plurality of testing sections located on the testing surface, the testing sections each configured to receive and test an individual image intensifier tube;
an input connector located at the first side edge of the testing surface, the input connector configured to removeably connect to an adjacent output connector of a first adjacent testing module; and
an output connector located at the second side of the testing surface, the output connector configured to removeably connect to an adjacent input connector of a second adjacent testing module.

9. The testing module of claim 8, wherein
the first side edge is a first longitudinal side edge,
the second side edge is a second longitudinal side edge opposite the first longitudinal side edge,
the testing surface further includes a first lateral side edge and a second lateral side edge, and
the first longitudinal side edge and the second longitudinal side edge are longer than the first lateral side edge and the second lateral side edge.

10. The testing module of claim 8, wherein
the plurality of testing sections are aligned in a row along the first longitudinal side and the second longitudinal side.

11. The testing module of claim 8, wherein
the input connector protrudes from the first side edge of the testing surface.

12. The testing module of claim 11, wherein
the output connector is located adjacent to the second side edge of the testing surface but does not protrude past the second side edge.

13. The testing module of claim 8, wherein
the substrate includes at least one first substrate connector located at the first side edge and at least one second substrate connector located at the second side edge.

14. The testing module of claim 8, wherein
each testing section includes a support cradle configured to support the individual image intensifier tube.

15. The testing module of claim 8, wherein
each testing section includes a contact portion including one or more electrical contacts configured to make electrical contact with corresponding electrical contacts on the individual image intensifier tube.

16. The testing module of claim 8, wherein
each testing section includes a visible indicator configured to indicate whether the individual image intensifier tube within that testing section has passed or failed a testing process.

17. A method of simultaneously testing a plurality of image intensifier tubes, the method comprising:
configuring a testing board by connecting a plurality of testing modules together or disconnecting one or more of the testing modules from the remainer of the plurality of testing modules forming the testing board;
connecting an input connector of one of the plurality of testing modules forming the testing board to a power supply unit;
connecting an output connector of one of the plurality of testing modules forming the testing board to a computer;
placing a plurality of image intensifier tubes on the plurality of testing modules forming the testing board; and
simultaneously testing operation of the plurality of image intensifier tubes using the power source, the testing board and the computer.

18. The method of claim 17, wherein
configuring the testing board includes connecting the plurality of testing modules together by connecting input connectors and output connectors of adjacent testing modules.

19. The method of claim 17, wherein
configuring the testing board includes disconnecting one or more of the testing modules by disconnecting an input connector of one testing module from an output connector of another testing module.

20. The method of claim 15, comprising
setting one or more testing parameters for the plurality of image intensifier tubes prior to testing the operation of the plurality of image intensifier tubes.
